(19) United States
(12) Patent Application Publication
(10) Pub. No.: US 2025/0120121 A1
(43) Pub. Date: Apr. 10, 2025

(54) SEMICONDUCTOR DEVICE

(71) Applicant: SAMSUNG ELECTRONICS CO., LTD., Suwon-si (KR)

(72) Inventors: Unki KIM, Suwon-si (KR); Kihwan Kim, Suwon-si (KR); Chanyoung Kim, Suwon-si (KR); Jeongho Yoo, Suwon-si (KR); Ingyu Jang, Suwon-si (KR); Sujin Jung, Suwon-si (KR)

(73) Assignee: SAMSUNG ELECTRONICS CO., LTD., Suwon-si (KR)

(21) Appl. No.: 18/733,327

(22) Filed: Jun. 4, 2024

(30) Foreign Application Priority Data
Oct. 5, 2023 (KR) 10-2023-0132459

(51) Int. Cl. H01L 29/786; H01L 29/06; H01L 29/16; H01L 29/167; H01L 29/423; H01L 29/66; H01L 29/775

(52) U.S. Cl. CPC H10D 30/6713; H10D 30/43; H10D 30/6735; H10D 30/6757; H10D 62/121; H10D 62/8325; H10D 62/834; H10D 64/018

(57) ABSTRACT

A semiconductor memory device is provided. The semiconductor memory device includes: a substrate; an active region extending in a first direction on the substrate; a plurality of channel layers stacked on the active region and spaced apart from each other in a vertical direction perpendicular to the first direction; a gate structure extending on the active region in a second direction perpendicular to the first direction and the vertical direction, and surrounding the plurality of channel layers; a source/drain region provided on at least one side of the gate structure on the active region and electrically connected to the plurality of channel layers; and a plurality of anti-diffusion layers stacked and spaced apart from each other in the vertical direction and extending in the second direction.

### CROSS-REFERENCE TO RELATED APPLICATION

This application claims priority to Korean Patent Application No. 10-2023-0132459, filed on Oct. 5, 2023, in the Korean Intellectual Property Office, the disclosure of which is incorporated by reference herein in its entirety.

### BACKGROUND

The present disclosure relates to a semiconductor device.

Recently, as down-scaling of integrated circuit (IC) devices has progressed rapidly, there is a need to secure not only high operation speed but also operation accuracy in IC devices. In addition, as the degree of integration of IC devices increases and the size of IC devices decreases, there is a need to develop a new structure that may improve performance and reliability in field effect transistors having a gate-all-around structure including a nanowire or nanosheet-shaped silicon body and a gate covering the silicon body.

### SUMMARY

One or more example embodiments provide a semiconductor device having improved reliability.

According to an aspect of an example embodiment, a semiconductor device includes: a substrate; an active region extending in a first direction on the substrate; a plurality of channel layers stacked on the active region and spaced apart from each other in a vertical direction perpendicular to the first direction; a gate structure extending on the active region in a second direction perpendicular to the first direction and the vertical direction, and surrounding the plurality of channel layers; a source/drain region provided on at least one side of the gate structure on the active region and electrically connected to the plurality of channel layers; and a plurality of anti-diffusion layers stacked and spaced apart from each other in the vertical direction and extending in the second direction. The plurality of anti-diffusion layers include a Si₁₋ₓGeₓ layer (here, x≠0), and the plurality of anti-diffusion layers are located only between the source/drain region and the plurality of channel layers to discontinuously extend in the vertical direction.

According to another aspect of an example embodiment, a semiconductor device includes: an active region extending in a first direction on a substrate; a plurality of source/drain regions provided on the active region; a plurality of channel layers provided on at least one side of and spaced apart from each of the plurality of source/drain regions in the first direction, electrically connected to the plurality of source/drain regions, and spaced apart from each other in a vertical direction perpendicular to the first direction; a plurality of anti-diffusion layers located on both sides of each of the plurality of source/drain regions on the active region and spaced apart from each other in the vertical direction; a gate structure extending in a second direction perpendicular to the first direction and the vertical direction on the active region, and surrounding the plurality of channel layers; and a source/drain capping layer on an upper surface of the plurality of source/drain regions in the vertical direction. A source/drain region of the plurality of source/drain regions is bilaterally symmetrical based on a central axis of the source/drain region. The plurality of anti-diffusion layers include a Si₁₋ₓGeₓ layer (here, x≠0). A thickness of each of the plurality of anti-diffusion layers in the first direction is about 0.1 nm to about 1 nm. The plurality of anti-diffusion layers are provided between the source/drain region and the plurality of channel layers, and discontinuously extend in the vertical direction.

According to another aspect of an example embodiment, a semiconductor device includes: an active region extending in a first direction on a substrate; a plurality of channel layers spaced apart from each other in a vertical direction perpendicular to the first direction on the active region and facing an upper surface of the active region; source/drain regions located on both sides of the plurality of channel layers on the active region and electrically connected to the plurality of channel layers; and a plurality of anti-diffusion layers spaced apart from each other in the vertical direction on the active region and extending in a second direction perpendicular to the first direction. The plurality of anti-diffusion layers include a Si₁₋ₓGeₓ layer (here, x≠0). The plurality of anti-diffusion layers are provided between a source/drain region, among the source/drain regions, and the plurality of channel layers and discontinuously extend in the vertical direction. The plurality of anti-diffusion layers are configured to prevent an N-type dopant diffusing from the source/drain region from reaching the plurality of channel layers. The source/drain region includes a first layer, a second layer, and a third layer sequentially stacked from outside the active region. The first layer, the second layer, and the third layer include an Si or SiC layer. The second layer doped with an N-type dopant at a first concentration and the third layer is doped with an N-type dopant at a second concentration different from the first concentration. When viewed in the second direction, a portion of one of the plurality of anti-diffusion layers facing the source/drain region has one of a rectangular shape parallel to a side of a channel layer in the first direction, a rounded circular arc shape, a shape with a rounded semicircular recess facing the channel layer, and a triangle shape with a peak point.

### BRIEF DESCRIPTION OF DRAWINGS

The above and other aspects and features will be more apparent from the following description of example embodiments, taken in conjunction with the accompanying drawings, in which:

FIG. 1 is a plan view of a semiconductor device according to an example embodiment;

FIG. 2A is a cross-sectional view illustrating a semiconductor device, taken along line I-I′ of FIG. 1, according to an example embodiment;

FIG. 2B is a cross-sectional view illustrating a semiconductor device, taken along line I-I′ of FIG. 1, according to another example embodiment;

FIGS. 3A, 3B, 3C and 3D are enlarged cross-sectional views of a local region indicated by “A” in FIG. 2A, according to example embodiments; and

FIGS. 4-6, 7A, 7B, 8A, 8B, 9, 10A, 10B, 11A and 11B are cross-sectional views illustrating a sequential process of a method of manufacturing a semiconductor device, according to an example embodiment.

### DETAILED DESCRIPTION

Hereinafter, example embodiments are described in detail with reference to the accompanying drawings. Embodiments described herein are example embodiments, and thus, the present disclosure is not limited thereto, and may be realized in various other forms. Each example embodiment provided in the following description is not excluded from being associated with one or more features of another example or another example embodiment also provided herein or not provided herein but consistent with the present disclosure. It will be understood that when an element or layer is referred to as being “on,” “connected to” or “coupled to” another element or layer, it can be directly on, connected or coupled to the other element or layer, or intervening elements or layers may be present. By contrast, when an element is referred to as being “directly on,” “directly connected to” or “directly coupled to” another element or layer, there are no intervening elements or layers present. It will be also understood that, even if a certain step or operation of manufacturing an apparatus or structure is described later than another step or operation, the step or operation may be performed later than the other step or operation unless the other step or operation is described as being performed after the step or operation. The same reference numerals are given to the same elements in the drawings, and repeated descriptions thereof are omitted.

The use of all examples or illustrative terms is simply for describing the technical idea in detail, and the scope is not limited by these examples or illustrative terms.

Unless otherwise specified below, horizontal directions parallel to the ground are a first direction X and a second direction Y perpendicular to the first direction X, and a direction perpendicular to the first direction X and the second direction Y vertical to the ground is described as a vertical direction Z.

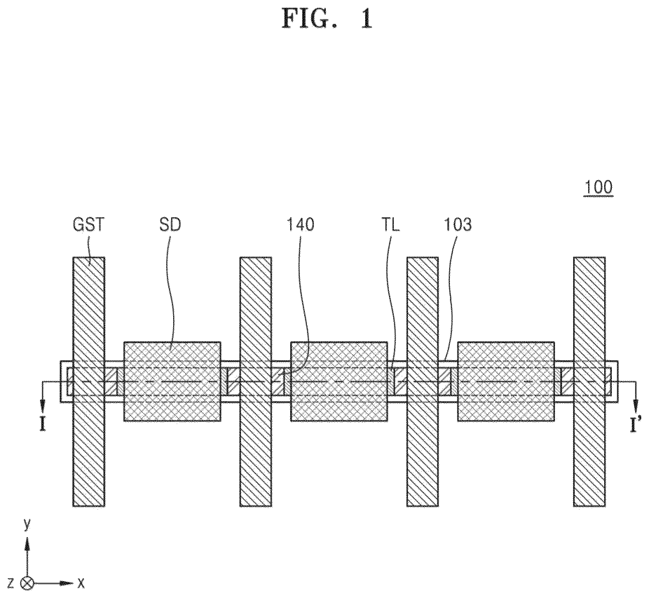

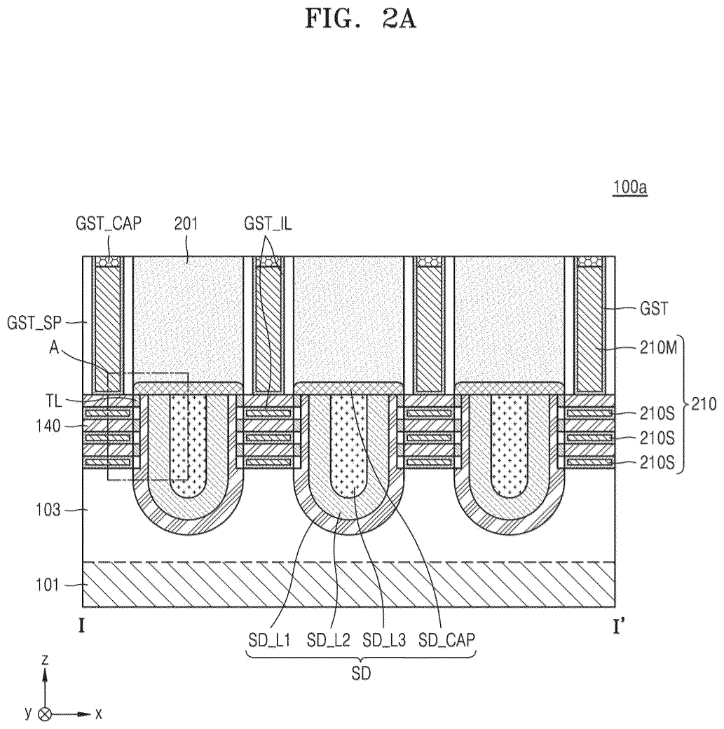

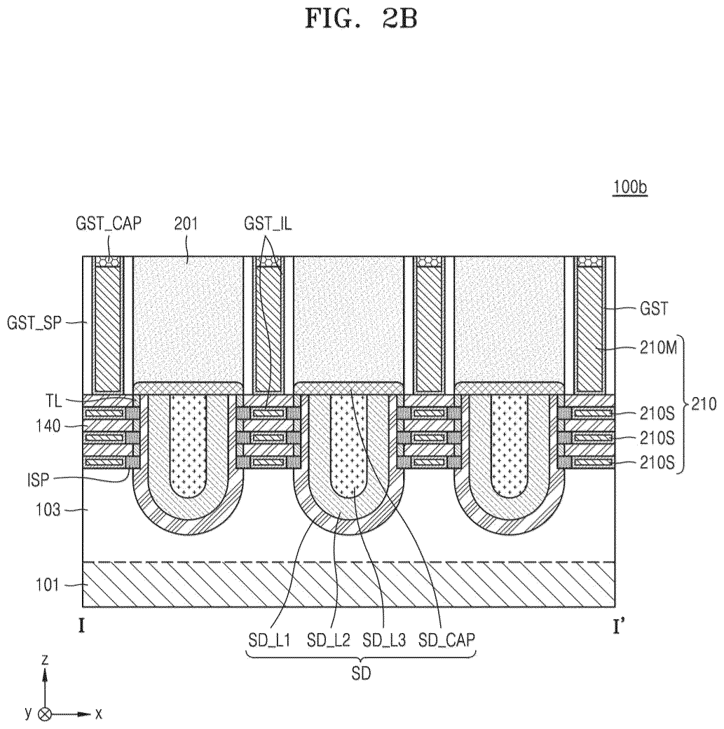

FIG. 1 is a plan view of a semiconductor device 100 according to an example embodiment. FIG. 2A is a cross-sectional view illustrating a semiconductor device 100a, taken along line I-I′ of FIG. 1, according to an example embodiment.

Referring to FIGS. 1 and 2A, the semiconductor device 100 or 100a may include a plurality of active regions 103 that protrude from a substrate 101 in the vertical direction Z and extend long in the first direction X, and a plurality of channel layers 140 disposed on the active regions 103. The term “channel layer” may also be referred to as “nanosheet” and refers to a conductive structure having a cross-section substantially vertical to a direction in which current flows. The nanosheets, which are channel layers, should be understood to include nanowires.

The substrate 101 may include a semiconductor, such as Si or Ge, or a compound semiconductor, such as SiGe, SiC, GaAs, InAs, InGaAs, or InP. The terms “SiGe”, “SiC”, “GaAs”, “InAs”, “InGaAs”, and “InP” refer to materials including elements included in each term, and are not chemical formulas representing stoichiometric relationships. In example embodiments, a main surface of the substrate 101 may have a surface orientation of the semiconductor device 100.

A device isolation film may be disposed on the substrate 101 to cover both sidewalls of each of the active regions 103. The device isolation film may include an oxide film, a nitride film, or combinations thereof.

Referring to FIG. 2A, the semiconductor device 100a may include a plurality of channel layers 140 that are stacked and spaced apart from each other in the vertical direction Z on the active region 103. The semiconductor device 100a may also include a gate structure GST extending in the second direction Y on the active region 103 and arranged to surround the channel layers 140. The gate structure GST may include a gate electrode 210 extending in the second direction Y on the active region 103, a gate insulating layer GST_IL surrounding the gate electrode 210, a gate spacer GST_SP covering side surfaces of the gate insulating layer GST_IL, and a gate capping layer GST_CAP covering the upper surface of the gate electrode 210. The gate electrode 210 may include a main gate electrode 210M extending in the second direction Y on the top of the channel layers 140 and at least one sub-gate electrode 210S located between each of the channel layers 140.

The gate capping layer GST_CAP may include a silicon nitride film. On the active region 103 and the device isolation layer, both sidewalls of each of the gate electrode 210 and the gate capping layer GST_CAP may be covered with a plurality of gate spacers GST_SP. The gate spacers GST_SP may cover the main gate electrode 210M and both sidewalls of the gate capping layer GST_CAP on the upper surfaces of the channel layers 140. Each of the gate spacers GST_SP may be spaced apart from the gate electrode 210 with the gate insulating layer GST_IL therebetween.

The gate spacers GST_SP may include silicon nitride (SiN), SiCN, SiBN, SiON, SiOCN, SiBCN, SiOC, silicon oxide (SiO), or combinations thereof. As used herein, the terms “SiN”, “SiCN”, “SiBN”, “SiON”, “SiOCN”, “SiBCN”, “SiOC”, and “SiO” refer to materials including elements included in each term, and are not chemical formulas representing stoichiometric relationships.

The gate electrodes 210 may extend long in the second direction Y. In regions in which the active regions 103 intersect with the gate electrodes 210, the channel layers 140 may be disposed on the upper surfaces of the active regions 103, respectively. Each of the channel layers 140 may face the upper surface of the active region 103 at a position spaced apart from the active region 103. The channel layers 140 may overlap each other in the vertical direction Z on the upper surface of the active region 103. The channel layers 140 may have different vertical distances (distances in the vertical direction Z) from the upper surface of the active region.

Although FIG. 1 illustrates a case in which a planar shape of the channel layer 140 is approximately square, example embodiments are not limited thereto. The channel layer 140 may have various planar shapes depending on a planar shape of each of the active region 103 and the gate electrode 210. In this example, a configuration in which the gate structure GST including the channel layers 140 and the gate electrodes 210 is formed on one active region 103 and the channel layers 140 are arranged in a row in the first direction X is illustrated. However, the number of channel layers 140 and the number of gate electrodes 210 disposed on one active region 103 are not particularly limited.

As illustrated in FIGS. 1 and 2A, the gate electrodes 210 may extend long in the second direction Y on the active region 103 and the device isolation layer. The gate electrodes 210 may cover the channel layers 140 on the active region 103 and surround the channel layers 140, respectively.

Each of the gate electrodes 210 may include a main gate electrode 210M and a plurality of sub-gate electrodes 210S. The main gate electrode 210M may cover the upper surface of the channel layer 140 and extend in the second direction Y. The sub-gate electrodes 210S may be integrally connected to the main gate electrode 210M and may be respectively located between the channel layers 140, and between the active region 103 and a lowermost one of the channel layers 140. In the vertical direction Z, a thickness of each of the sub-gate electrodes 210S may be less than a thickness of the main gate electrode 210M. The gate electrode 210 may include a metal, a metal nitride, a metal carbide, or combinations thereof. The metal may be selected from Ti, W, Ru, Nb, Mo, Hf, Ni, Co, Pt, Yb, Tb, Dy, Er, and Pd. The metal nitride may be selected from TiN and TaN. The metal carbide may be TiAlC.

A plurality of source/drain regions SD may be disposed on the active region 103 at positions adjacent to the gate electrode 210 in the first direction X. The source/drain regions SD may each face the channel layer 140 and the sub-gate electrodes 210S in the first direction X.

A gate insulating layer GST_IL may be located between the channel layer 140 and a gate electrode 210. In example embodiments, the gate insulating layer GST_IL may have a stack structure including an interface film and a high-k film. The interface film may include a low-k material film having a dielectric constant of about 9 or less, for example, a silicon oxide film, a silicon oxynitride film, or combinations thereof. In example embodiments, the interface film may be omitted. The high-k film may include a material having a dielectric constant higher than that of a silicon oxide film. For example, the high-k film may have a dielectric constant of about 10 to about 25. The high-k film may include a hafnium oxide, but example embodiments are not limited thereto.

A plurality of transistors may be formed in portions in which the active regions 103 and the gate electrodes 210 intersect on the substrate 101.

In example embodiments, the channel layers 140 may include semiconductor layers including the same element. In an example, each of the channel layers 140 may include a Si layer. The channel layers 140 may be doped with a dopant of the same conductivity type as that of the source/drain region SD. In an example, the channel layers 140 may include a Si layer doped with an N-type dopant. The N-type dopant may be selected from P, As, and Sb, but example embodiments are not limited thereto.

Each of the channel layers 140 may have a channel region. For example, the channel layers 140 may each have a thickness selected within the range of about 4 nm to about 6 nm, but example embodiments are not limited thereto. Here, the thickness of each of the channel layers 140 refers to a size in the vertical direction Z. In example embodiments, the channel layers 140 may have substantially the same thickness in the vertical direction Z. In other example embodiments, at least some of the channel layers 140 may have different thicknesses in the vertical direction Z.

In some example embodiments, at least some of the channel layers 140 may have substantially the same or similar size in the first direction X. In some other example embodiments, at least some of the channel layers 140 may have different sizes in the first direction X. For example, a length of the channel layer 140 relatively close to the upper surface of the active region 103, among the channel layers 140, in the first direction may be less than a length of the channel layer 140 farthest from the upper surface of the active region 103. In this case, an effective channel length of a channel formed in the channel layer relatively close to the upper surface of the active region 103 may be less than an effective channel length of a channel formed in the channel layer 140 farthest from the upper surface of the active region 103, and accordingly, the amount of current flowing through the channel layer relatively close to the upper surface of the active region 103 may increase under the same operating voltage.

A plurality of recesses may be formed in the active region 103. Here, a recess refers to a region in which at least a portion of the active region 103 is etched, and which may accommodate the source/drain region SD. Although FIGS. 2A and 2B illustrate a case in which a level of the lowermost surface of each of the recesses is lower than a level of the upper surface of the active region 103, example embodiments are not limited thereto. The level of the lowermost surface of each of the recesses may be approximately the same as or similar to the level of the upper surface of the active region 103. In example embodiments, a vertical distance between the level of the lowermost surface of each of the recesses and the level of the upper surface of the active region 103 may be about 0 nm to about 20 nm, but example embodiments are not limited thereto. The term “level” used herein refers to a distance from the bottom of the substrate 101 in the vertical direction (Z or −Z).

The source/drain regions SD may be disposed on the recesses. The source/drain regions SD may contact adjacent channel layers 140, respectively. In this regard, the semiconductor device 100a according to an example embodiment may include the source/drain region SD disposed on at least one side of the gate structure GST on the active region 103 and electrically connected to the channel layers 140.

The source/drain regions SD may include an epitaxially grown semiconductor layer. Each of the source/drain regions SD may include a vertical overgrowth portion at a higher level than that of the upper surface of the channel layers 140 in the vertical direction Z. In addition, the source/drain region SD may further include a source/drain capping layer SD_CAP disposed on an upper surface of the source/drain region SD in the vertical direction Z, and the source/drain capping layer SD_CAP may include an undoped Si layer or a Si layer including an N-type dopant.

In embodiments, each of the source/drain regions SD may include a Si layer doped with an N-type dopant. The N-type dopant may be selected from phosphorus (P), arsenic (As), and antimony (Sb), but is not limited thereto. In detail, the source/drain region SD may include a first layer SD_L1, a second layer SD_L2, and a third layer SD_L3 sequentially stacked in a direction from the outside adjacent to the active region 103 to a central axis of the source/drain region SD. The first layer SD_L1, the second layer SD_L2, and the third layer SD_L3 may include an Si or SiC layer. The first layer SD_L1 may include an undoped Si layer. The second layer SD_L2 and the third layer SD_L3 may be doped with N-type dopants at different concentrations, respectively. The third layer SD_L3 may be formed as a single crystalline layer. In the single crystalline third layer SD_L3, a silicon crystal array may be regularly continuous.

The semiconductor devices 100 and 100a may include a plurality of anti-diffusion layers TL that are stacked on the active region 103 to be spaced apart from each other in the vertical direction Z and extend in the second direction Y. The anti-diffusion layers TL may include a Si₁₋ₓGeₓ layer (here, x≠0). Referring to FIG. 1, a plurality of anti-diffusion layers TL may be disposed only on the sides of the channel layer 140. Referring to FIG. 2A together, the anti-diffusion layers TL may be disposed only between the source/drain region SD and the channel layers 140. The anti-diffusion layers TL may extend discontinuously in the vertical direction Z. That is, the source/drain region SD may face the channel layers 140 with the anti-diffusion layers TL therebetween in the first direction X, and the anti-diffusion layers TL may not be located between the source/drain region SD and the sub-gate electrodes 210S.

A thickness of the anti-diffusion layers TL in the first direction X may be about 0.1 nm to about 1 nm, and the anti-diffusion layers TL may be configured to prevent the N-type dopant diffused from the source/drain region SD from reaching the channel layer 140. To prevent diffusion occurring in the third layer SD_L3, which is an internal layer of the source/drain region SD, a SiAs layer was applied to surround the inner side, and a concentration of As had to be increased to improve a diffusion prevention ability of the SiAs layer. In order to compensate for a deterioration in resistance performance caused in the process of increasing the concentration of the third layer SD_L3, the anti-diffusion layer TL may be formed only between the source/drain region SD and the channel layer 140, thereby preventing the deterioration in resistance performance and spreading at the same time. A length of the anti-diffusion layers TL in the vertical direction Z may be equal to or less than a length of the channel layer 140 in the vertical direction Z. Although the anti-diffusion layers TL are shown to overlap the first layer SD_L1 of the source/drain region SD when viewed in the second direction Y, the anti-diffusion layers TL may not interfere with the first layer SD_L1 of the source/drain region SD when viewed in the second direction Y. Here, not interfering means not being formed repeatedly in the same region, and this is the same hereinafter.

The anti-diffusion layers TL are located on both ends of the channel layer 140 in the first direction such that the channel layer 140 may not be in direct contact with at least a partial region of the source/drain region SD. However, even in this case, the source/drain region SD may be electrically connected to the channel layers 140 through the anti-diffusion layer TL.

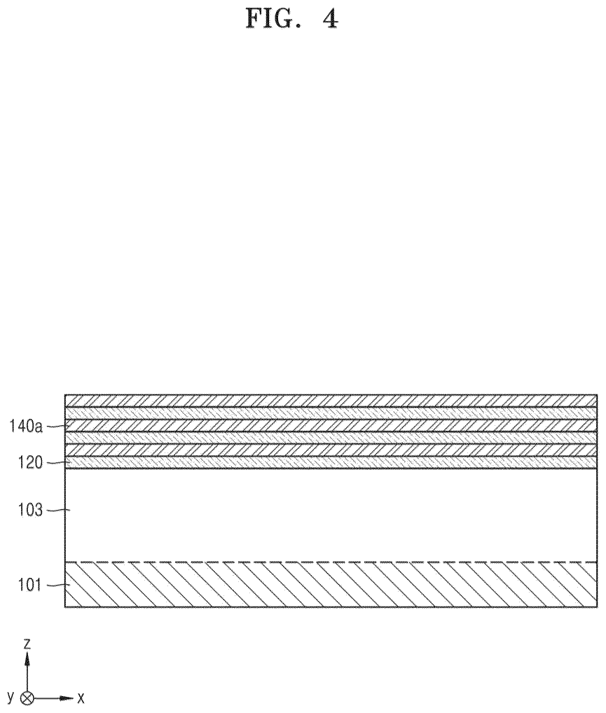

A process of forming the anti-diffusion layers TL only on the side of the channel layer 140 is described in detail with reference to FIG. 4 and the following drawings.

FIG. 2B is a cross-sectional view illustrating a semiconductor device 100b, taken along line I-I′ of FIG. 1, according to another example embodiment.

For convenience of description, the differences from FIG. 2A are mainly described. Referring to FIG. 2B, the semiconductor device 100b may include internal spacers ISP located between the sub-gate electrodes 210S and the source/drain region SD on the active region 103 and stacked to be spaced apart from each other in the vertical direction Z.

A plurality of internal spacers ISPs may be located between each of the channel layers 140, and between the active region 103 and the lowermost channel layer 140. Both sidewalls of each of the sub-gate electrodes 210S may be covered with the internal spacer ISP with the gate insulating layer GST_IL therebetween. The sub-gate electrodes 210S may be spaced apart from the source/drain region SD with the gate insulating layer GST_IL and the internal spacer ISP therebetween. At least some of the internal spacers ISP may overlap the gate spacer GST_SP in the vertical direction Z. Each of the source/drain regions SD may contact the internal spacers ISP adjacent thereto.

A distance between the internal spacers ISP in the vertical direction Z may be equal to lengths of the channel layer 140 and the anti-diffusion layer TL in the vertical direction Z, but example embodiments are not limited thereto.

The side of the internal spacer ISP facing the source/drain region SD may be formed to coincide with the side of the anti-diffusion layer TL facing the source/drain region SD.

The internal spacer ISP may include a silicon nitride (SiN), SiCN, SiBN, SiON, SiOCN, SiBCN, SiOC, a silicon oxide (SiO), or combinations thereof. The internal spacer ISP may further include an air gap. In example embodiments, the gate spacer GST_SP and the internal spacer ISP may include the same material. In other example embodiments, the gate spacer GST_SP and the internal spacer ISP may include different materials.

The source/drain regions SD may include portions that are in contact with the gate spacers GST_SP adjacent thereto as shown in FIG. 2A or may include portions that are in contact with the internal spacers ISP adjacent thereto as shown in FIG. 2B.

Referring to FIGS. 2A and 2B together, the anti-diffusion layers TL may be disposed on both ends of the channel layer 140 regardless of the presence or absence of the internal spacer ISP, and the anti-diffusion layer TL may not interfere with the internal spacer ISP.

The internal spacer ISP is shown as having a rectangular cross-section viewed in the second direction Y, but example embodiments are not limited thereto. A portion of the internal spacer ISP facing the source/drain region SD may have various shapes, including a rectangular shape parallel to the side of the channel layer 140 in the first direction X, a rounded arc shape, a shape having a rounded semicircular recess toward the channel layer 140, and a triangular shape with a peak point. The internal spacer ISP may be formed at both ends of a sacrificial layer (120 in FIG. 4A), and may remain without being removed during a process in which the sacrificial layer (120 in FIG. 4A) is removed.

Between each of the channel layers 140, and between the active region 103 and the lowermost channel layer 140, both sidewalls of each of the sub-gate electrodes 210S may be spaced apart from the source/drain region SD with the gate insulating layer GST_IL and the internal spacer ISP therebetween. As shown in FIG. 2B, the gate insulating layer GST_IL may not include a portion in contact with the source/drain region SD. For example, the gate insulating layer GST_IL may be spaced apart from the source/drain region SD. The source/drain regions SD may each face the channel layers 140 and the sub-gate electrodes 210S in the first direction X.

The gate spacers GST_SP and the source/drain regions SD may be covered with a protective insulating film. The protective insulating film may include a silicon nitride (SiN), a silicon oxide (SiO), SiCN, SiBN, SiON, SiOCN, SiBCN, SiOC, or combinations thereof. In example embodiments, the protective insulating film may be in contact with an upper surface of the source/drain region SD. In other example embodiments, the protective insulating film may be omitted.

An inter-gate insulating layer 201 may be formed on the protective insulating film. The inter-gate insulating layer 201 may include a silicon nitride film, a silicon oxide film, SiON, SiOCN, or combinations thereof. When the protective insulating film is omitted, the inter-gate insulating layer 201 may contact the source/drain region 130.

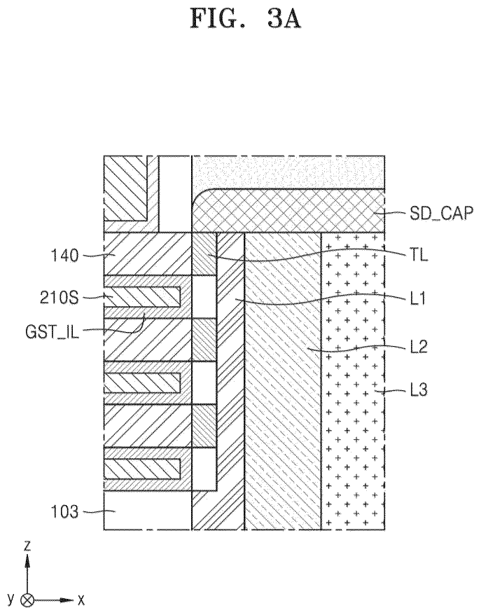

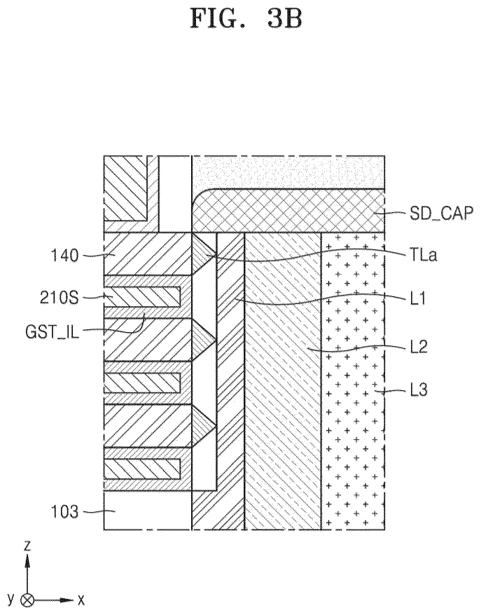

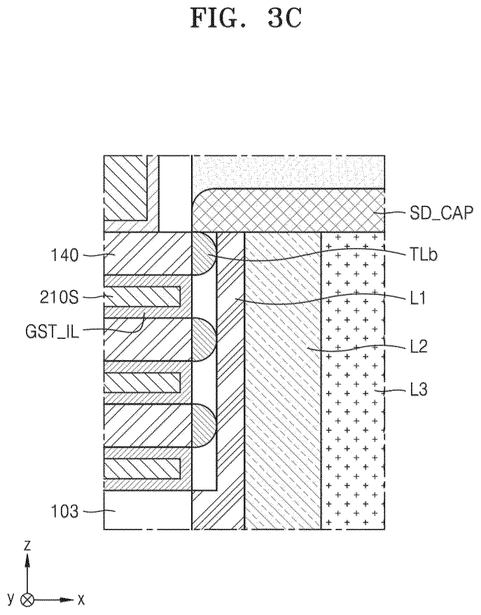

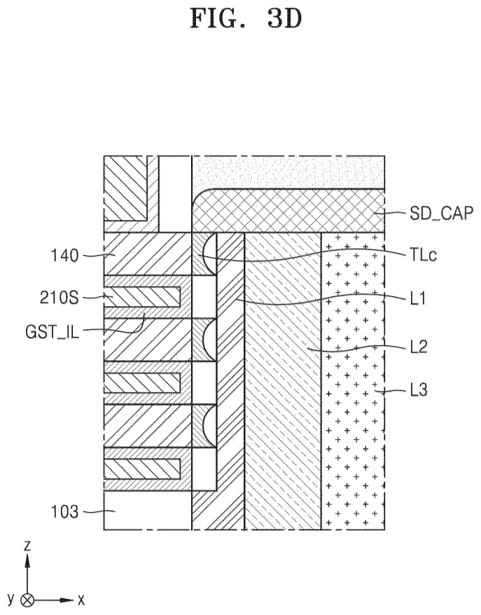

FIG. 3A is an enlarged cross-sectional view of a local region indicated by “A” in FIG. 2A, according to an example embodiment, and FIGS. 3B to 3D are enlarged cross-sectional views according to another example embodiment.

Referring to FIG. 3A, the anti-diffusion layers TL may be formed to have a thickness in the first direction X on the sidewall of each of the channel layers 140. The anti-diffusion layers TL may be formed without interfering with the source/drain region SD. The source/drain region SD may include a first layer SD_L1, a second layer SD_L2, and a third layer SD_L3 sequentially stacked in a direction from the outside adjacent to the active region 103 to a central axis of a source/drain.

When viewed in the second direction Y, the first layer L1 may be formed without interfering with the anti-diffusion layers TL.

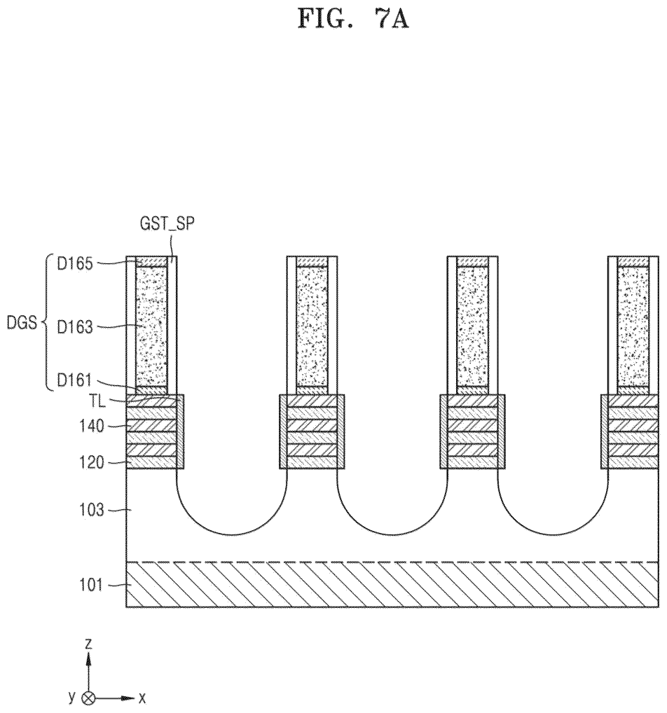

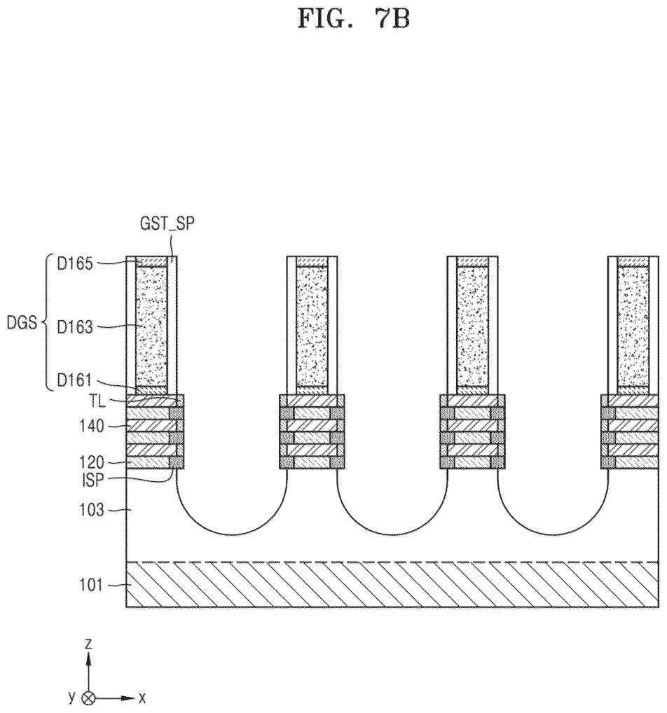

The sides of the anti-diffusion layers TL facing the source/drain region SD may have a rectangular shape formed to be parallel to the sidewall of the channel layers 140. A length of the anti-diffusion layers TL in the vertical direction Z may be equal to a length of the channel layer 140 in the vertical direction Z. Accordingly, the anti-diffusion layers TL may be formed only between the source/drain region SD and the channel layers 140, and discontinuously extend in the vertical direction Z. The anti-diffusion layers TL may not be formed on the side of the sub-gate electrode 210S. Referring to FIG. 7A, the anti-diffusion layers TL may be formed not only on the sidewalls of the channel layers 140 but also on the sidewalls of the sacrificial layer (120 in FIG. 7A) during the process, but the anti-diffusion layer TL corresponding to the other regions except for the sidewalls may be removed together when the sacrificial layer (120 in FIG. 7A) is removed.

Referring to FIGS. 3B to 3D, a plurality of anti-diffusion layers TLa, TLb, and TLc may be formed in different shapes. In detail, referring to FIG. 3B, the anti-diffusion layer TLa may have a triangular shape with a peak point formed at a portion facing the source/drain region SD. As shown in FIG. 3B, the triangle may be an isosceles triangle in which both sides, excluding the side in contact with the channel layer 140, have the same slope and the same length, but example embodiments are not limited thereto, and the triangle may have different shapes. The anti-diffusion layers TLa, TLb, and TLc may be formed in different shapes depending on an injection direction and airflow direction of an etching gas during a process of etching the sacrificial layer (120 in FIG. 4).

When the anti-diffusion layer TLa has a triangular shape, a distance from the sidewall of the channel layer 140 to the peak point of the anti-diffusion layer TLa may be shorter or equal to a distance from the sidewall of the channel layer 140 to the peak point of the anti-diffusion layer TL when the anti-diffusion layer TL has a rectangular shape.

Referring to FIG. 3C, a portion of the anti-diffusion layer TLb facing the source/drain region SD may have a rounded circular arc shape. Referring to FIG. 3D, a portion of the anti-diffusion layer TLc facing the source/drain region SD may have a shape of a recess rounded toward the channel layer 140. The curvature of the rounded shape is not limited to that shown in FIGS. 3C and 3D. When the anti-diffusion layer TLb has the rounded circular arc shape or when the anti-diffusion layer TLc has the rounded recess shape, the distance from the sidewall of the channel layer 140 to the peak points of the anti-diffusion layers TLb and TLc may be less than or equal to the distance from the sidewall of the channel layer 140 to the peak point of the anti-diffusion layer TL when the anti-diffusion layer TL of FIG. 3A has a rectangular shape.

FIGS. 4 to 11B are cross-sectional views illustrating a sequential process of a method of manufacturing a semiconductor device, according to an example embodiment.

A manufacturing method of the semiconductor devices 100, 100a, and 100b illustrated in FIGS. 1 to 2B is described with reference to FIGS. 4 to 11B. In FIGS. 4 to 11B, the same reference numerals as those of FIGS. 1 to 2B denote the same members, and detailed description thereof is omitted here.

Referring to FIG. 4, after a plurality of sacrificial layers 120 and a plurality of semiconductor layers 140a are alternately stacked one layer at a time on the substrate 101.

A stack structure of the sacrificial layers 120 and the semiconductor layers 140a may remain on the upper surface of each of the active regions 103.

The sacrificial layers 120 may include semiconductor materials having an etch selectivity with respect to the semiconductor layers 140a. In example embodiments, the semiconductor layers 140a may include a Si layer, and the sacrificial layers 120 may include a SiGe layer. In example embodiments, a Ge content within the sacrificial layers 120 may be constant. The SiGe layer constituting the sacrificial layers 120 may have a constant Ge content selected within the range of about 5 atomic % to about 60 atomic %, for example, about 10 atomic % to about 40 atomic %. The Ge content in the SiGe layer constituting the sacrificial layers 120 may be selected to vary according to needs.

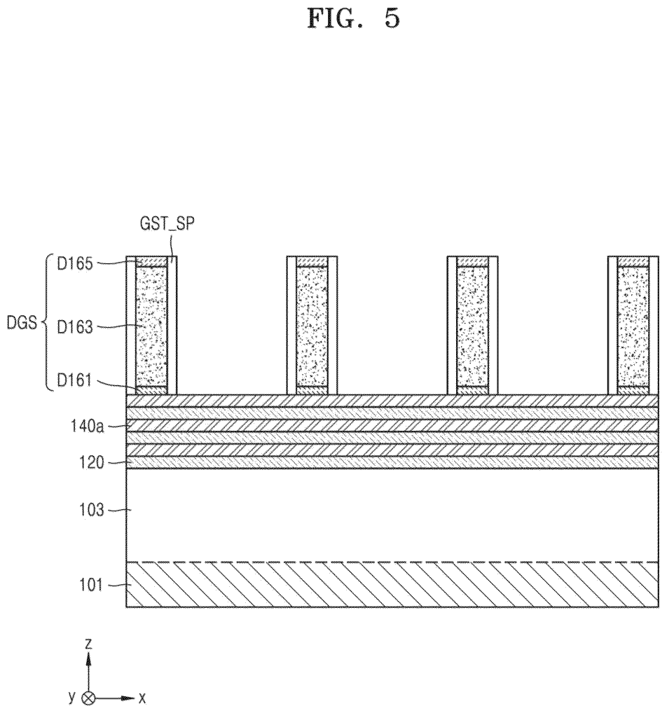

Referring to FIG. 5, a plurality of dummy gate structures DGS may be formed on the stack structure of the sacrificial layers 120 and the semiconductor layers 140a.

Each of the dummy gate structures DGS may be formed to extend long in the second direction Y. The dummy gate structures DGS may each include an oxide film D161, a dummy gate layer D163, and a capping layer D165 sequentially stacked on the substrate 101. In example embodiments, the dummy gate layer D163 may include polysilicon, and the capping layer D165 may include a silicon nitride film.

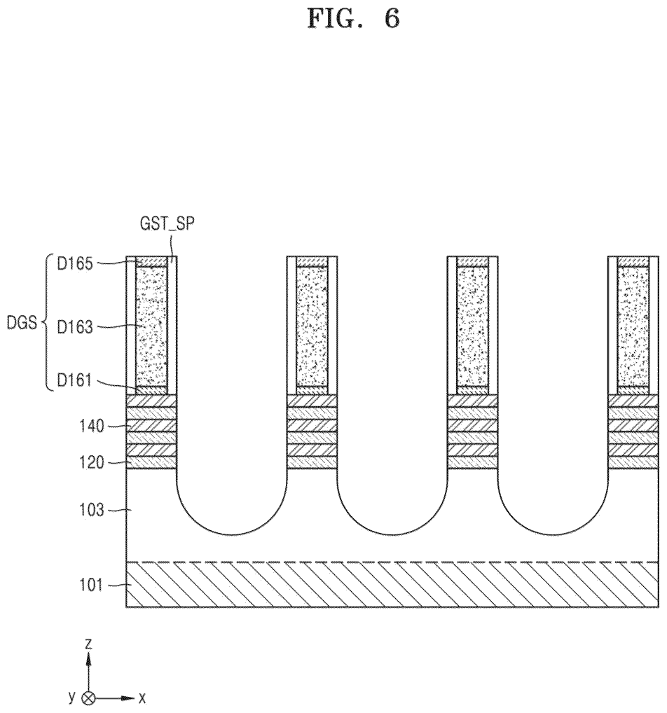

Referring to FIG. 6, after forming the gate spacers GST_SP covering both sidewalls of each of the dummy gate structures DGS, portions of the sacrificial layers 120 and the channel layers 140 may be removed using the dummy gate structures DGS and the gate spacers GST_SP to divide the channel layers 140. For example, some of the sacrificial layers 120 and the semiconductor layers 140a and a portion of the substrate 101 may be etched to expose a plurality of active regions 103 on the substrate 101. Each of the channel layers 140 may include a plurality of nanosheets. Thereafter, the active region 103 exposed between each of the channel layers 140 may be etched to form a plurality of recesses in an upper portion of the active region 103. To form the recesses, the active region 103 may be etched using dry etching, wet etching, or combinations thereof. A device isolation film may be formed to cover the sidewall of each of the active regions 103. An upper surface of the device isolation film may be at a level approximately the same as or similar to that of the upper surface of the active region 103.

FIG. 7A is a cross-sectional view illustrating a portion of the process of forming the structure of FIG. 2A. Referring to FIG. 7A, the anti-diffusion layers TL may be formed in the recess spaces. FIG. 7A shows a state after the anti-diffusion layers TL are etched in the uppermost region of the active region 103. After the uppermost region of the active region 103 is etched, the anti-diffusion layers TL may exist only on both sides of the channel layer 140 and the sacrificial layer 120. As shown, the anti-diffusion layers TL may have a uniform thickness, but example embodiments are not limited thereto.

FIG. 7B is a cross-sectional view illustrating a portion of the process of forming the structure of FIG. 2B. Referring to FIG. 7B, portions of the sacrificial layers 120 exposed from both sides of each of the channel layers 140 may be removed to form a plurality of indented regions between each of the channel layers 140. In order to form the indented regions, portions of the sacrificial layers 120 may be selectively etched by using the difference in etch selectivity between the sacrificial layers 120 and the channel layers 140. Thereafter, the internal spacers ISPs filling the indented regions may be formed. To form the internal spacers ISPs, an atomic layer deposition (ALD) process, a chemical vapor deposition (CVD) process, an oxidation process, or combinations thereof may be used. The internal spacer ISP may include, but is not limited to, SiN, SiO₂, and mixtures thereof.

After the anti-diffusion layers TL are formed, an etching region connected to the indented regions mentioned above may be formed in a region of the anti-diffusion layers TL adjacent to the sacrificial layer 120. An internal spacer ISP may be formed in an etched region formed in the indented regions and the anti-diffusion layers TL. In the process of etching the sacrificial layer 120, the sides of each of the channel layers 140 and the sacrificial layers 120 in the first direction X toward the source/drain regions may be formed to be different from each other. The sides of each of the anti-diffusion layers TL and the internal spacers ISP that face away from the source/drain regions in the first direction X may be formed to be different from each other.

FIG. 7B illustrates a state after the anti-diffusion layers TL are etched in the uppermost region of the active region 103. After the uppermost region of the active region 103 is etched, the anti-diffusion layers TL may exist only on both sides of the channel layer 140 and the sacrificial layer 120. The anti-diffusion layers TL are shown to have a uniform thickness, but example embodiments are not limited thereto.

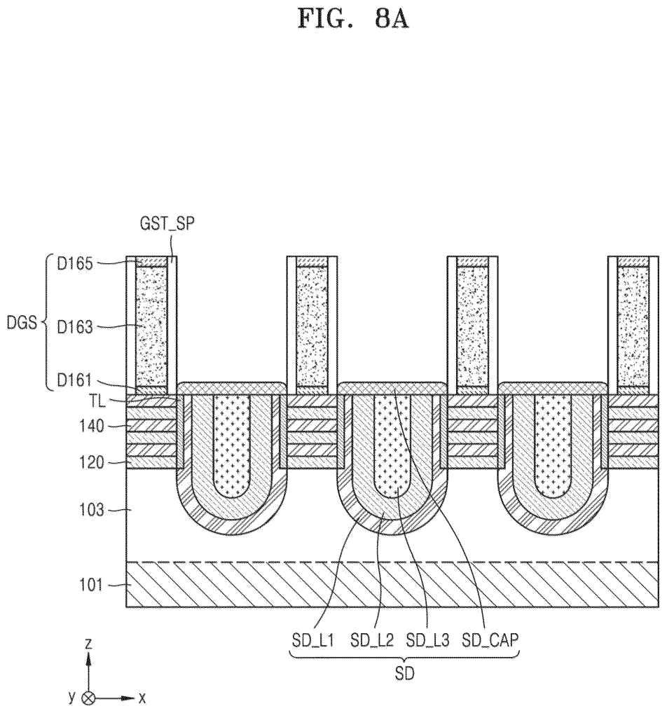

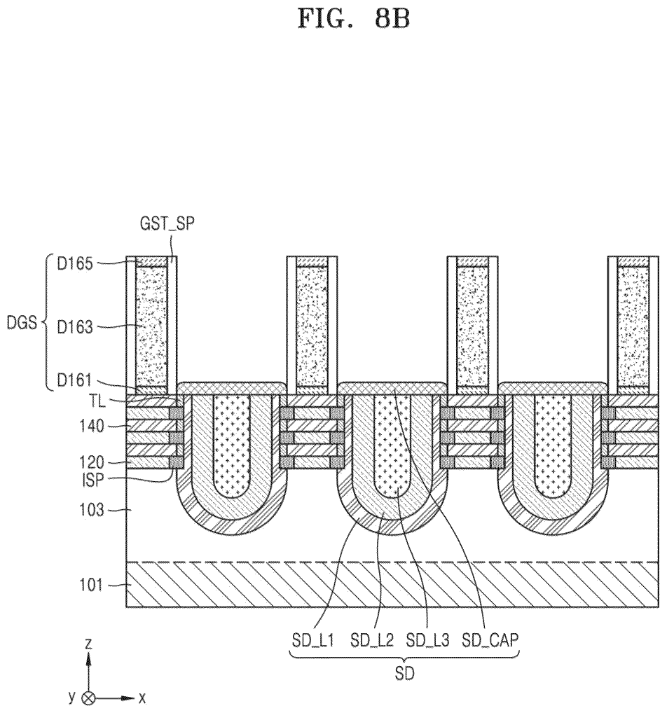

FIG. 8A is a cross-sectional view illustrating a portion of the process of forming the structure of FIG. 2A. FIG. 8B is a cross-sectional view illustrating a portion of the process of forming the structure of FIG. 2B.

Referring to FIGS. 8A and 8B, the source/drain regions SD may be formed on the active regions 103. The first layer SD_L1, the second layer SD_L2, and the third layer SD_L3 may be sequentially formed in the recess regions. For example, selective epitaxial growth process may be performed to form the source/drain regions 130 on the active region 103 on both sides of each of the channel layers 140.

A thickness of each of the first layer SD_L1, the second layer SD_L2, and the third layer SD_L3 may be different in the vertical direction Z or the first direction X, and a thickness of the third layer SD_L3 may be greater than thicknesses of the first layer SD_L1 and the second layer SD_L2. At least a portion of each of outer peripheral surfaces of the first layer SD_L1, the second layer SD_L2, and the third layer SD_L3 may be rounded, and a peak point of each of the first layer SD_L1, the second layer SD_L2, and the third layer SD_L3 in the vertical direction may be formed as an inflection point. However, the shapes of the first layer SD_L1, the second layer SD_L2, and the third layer SD_L3 are not limited to those shown.

The first layer SD_L1, the second layer SD_L2, and the third layer SD_L3 may include a Si or SiC layer, and the second layer SD_L2 and third layer SD_L3 may be doped with N-type dopants having different concentrations. The concentration of the N-type dopant of the third layer SD_L3 may be higher than the concentration of the N-type dopant of the second layer SD_L3. The first layer SD_L1 may include an undoped Si layer. The N-type dopant doped in the second layer SD_L2 may be arsenic (As). The N-type dopant doped in the third layer SD_L3 may be phosphorus (P), arsenic (As), antimony (Sb), or a mixture thereof.

In an initial stage of the selective epitaxial growth process, a semiconductor film may be epitaxially grown from the surface of the active region 103 exposed from the bottom of the recess and the sidewall of each of the anti-diffusion layers TL. The semiconductor film may include silicon doped with N-type impurities. Thereafter, as the selective epitaxial growth process progresses, the semiconductor film may gradually grow to obtain the source/drain regions SD as illustrated, and the first layer SD_L1, the second layer SD_L2, and the third layer SD_L3 may be formed sequentially.

In example embodiments, raw materials including an elemental semiconductor precursor may be used to form the source/drain region SD by the selective epitaxial growth process. The elemental semiconductor precursor may include the element Si. When the source/drain region SD includes a silicon film, a Si source may be used to form the source/drain region SD. As the Si source, silane (SiH₄), disilane (Si₂H₆), trisilane (Si₃H₈), dichlorosilane (SiH₂Cl₂), etc. may be used, but example embodiments are not limited thereto. In example embodiments, when the source/drain region 130 includes a silicon film doped with P (phosphorus), a P source may be used in addition to the Si source to form the P (phosphorus)-doped silicon film. Phosphorus oxychloride (POCl₃) may be used as the P source, but example embodiments are not limited thereto. In example embodiments, a P dopant ion implantation process using the P source may be performed in-situ during the epitaxial growth process to form the source/drain region SD.

The source/drain region SD may include the source/drain capping layer SD_CAP disposed on the upper surface of the source/drain region SD in the vertical direction Z. The source/drain capping layer SD_CAP may include an undoped Si layer or a Si layer including an N-type dopant.

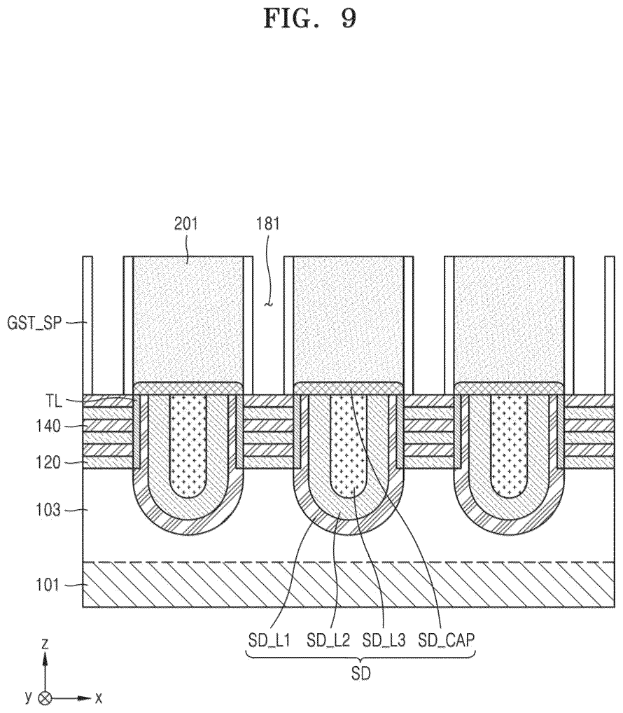

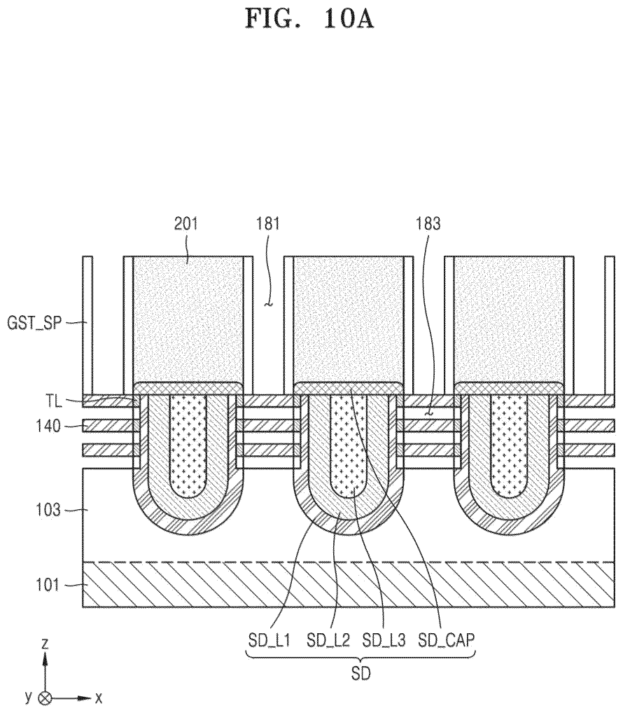

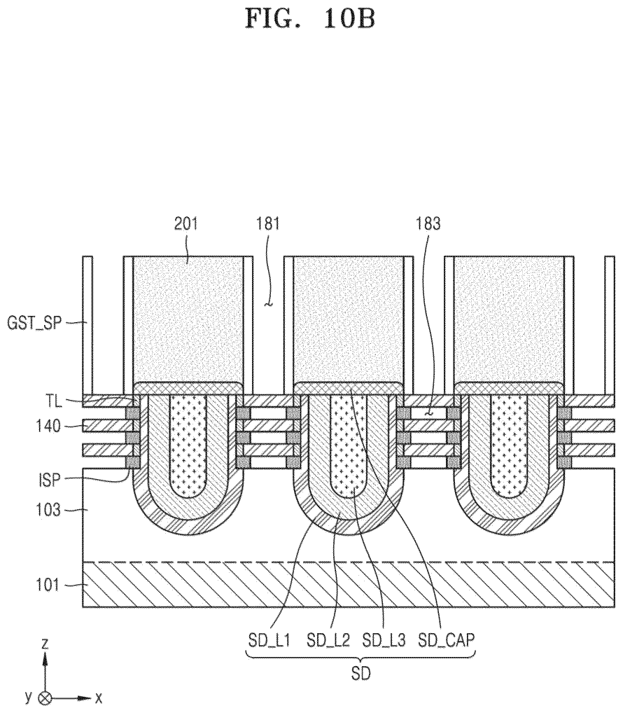

FIG. 9 is a cross-sectional view illustrating a portion of the process of forming the structure of FIGS. 2A and 2B. FIG. 10A is a cross-sectional view illustrating a portion of the process of forming the structure of FIG. 2A. FIG. 10B is a cross-sectional view illustrating a portion of the process of forming the structure of FIG. 2B. Referring to FIGS. 9, 10A, and 10B together with FIG. 8A, the inter-gate insulating layer 201 may be formed to cover the result of FIG. 8A in which the source/drain regions SD are formed. The inter-gate insulating layer 201 may be planarized to expose the upper surface of the capping layer D165. Thereafter, the capping layer D165 may be removed to expose an upper surface of the dummy gate layer D163, and the inter-gate insulating layer D163 may be partially removed so that an upper surface of the inter-gate insulating layer 201 is at approximately the same level as that of the upper surface of the dummy gate layer D163.

Thereafter, the dummy gate layer D163 and the oxide film D161 therebelow may be sequentially removed. A first gate space 181 may be prepared by removing the dummy gate layer D163 and the oxide film D161 below the dummy gate layer D163, and a plurality of nanosheet stacks (NSS) may be exposed through the first gate space 181. Thereafter, the sacrificial layers 120 remaining on the active region 103 may be removed through the first gate space 181 to form the second gate space 183 in space between each of the channel layers 140 and in space between the lowermost channel layer and the upper surface of the active region 103.

In example embodiments, in order to selectively remove the sacrificial layers 120, the difference in etch selectivity between the channel layers 140 and the sacrificial layers 120 may be used. A liquid or gaseous etchant may be used to selectively remove the sacrificial layers 120. In example embodiments, a CH₃COOH-based etchant, for example, an etchant including a mixture of CH₃COOH, HNO₃, and HF, or an etchant including a mixture of CH₃COOH, H₂O₂, and HF, may be used to selectively remove the sacrificial layers 120, but is not limited to the above examples.

During the process of removing the sacrificial layers 120, the anti-diffusion layer TL on both sides of the sacrificial layer 120 may be removed. In this case, the anti-diffusion layer TL on both sides of the channel layer 140 may not be removed. Accordingly, the source/drain region SD may face the channel layers 140 with the anti-diffusion layers TL therebetween in the first direction X, and the anti-diffusion layers TL may not be in the source/drain region SD and the second gate space 183.

As shown in FIGS. 10A and 10B, the sacrificial layer 120 and the anti-diffusion layer TL on both sides of the sacrificial layer 120 may be removed regardless of the presence or absence of the internal spacer ISP.

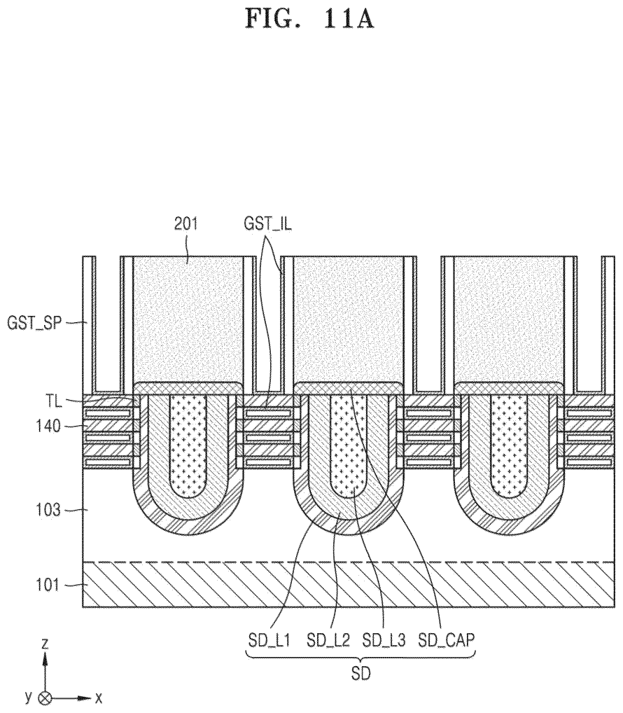

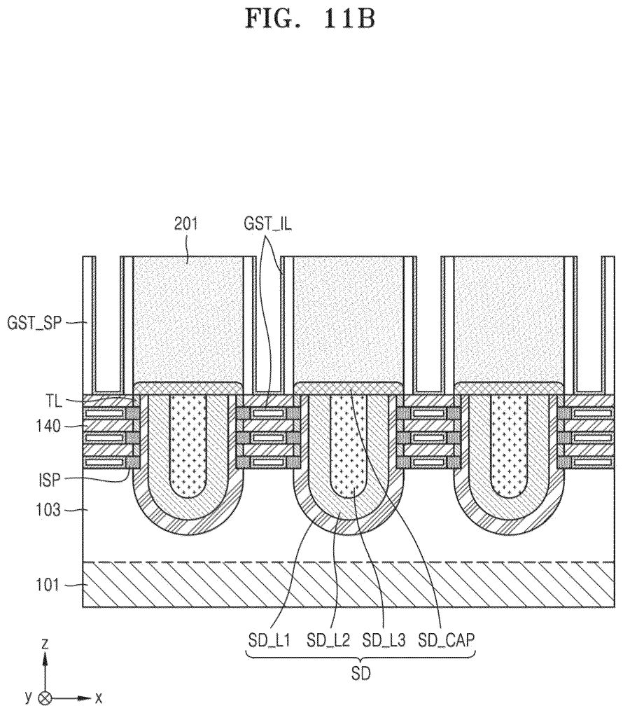

Referring to FIGS. 11A and 11B, the gate insulating layer GST_IL may be formed to cover the exposed surfaces of the channel layers 140 and the active region 103. An ALD process may be used to form the gate insulating layer GST_IL. As shown in FIGS. 11A and 11B, the gate insulating layer GST_IL may be removed regardless of the presence or absence of the internal spacer ISP.

Referring to FIGS. 11A and 11B together with FIGS. 2A and 2B, a conductive layer for forming a gate covering the upper surface of the inter-gate insulating layer 201, while filling the gate space (181 and 183 in FIG. 10B) on the gate insulating layer GST_IL, may be formed. The conductive layer for forming a gate is configured to serve as the gate electrode 210. The conductive layer for forming a gate may include metal, a metal nitride, a metal carbide, or combinations thereof. An ALD process or a CVD process may be used to form the conductive layer for forming a gate. The gate structure GST may be formed by partially removing an upper portion of the gate spaces (181 and 183 in FIG. 10B) so that the upper surface of the inter-gate insulating layer 201 is exposed and the upper portion of the gate spaces is emptied. Thereafter, the gate capping layer GST_CAP filling the removed gate spaces (181 and 183 in FIG. 10B) may be formed to form the semiconductor devices 100a and 100b of FIGS. 2A and 2B.

Methods of manufacturing the semiconductor devices 100, 100a, and 100b illustrated in FIGS. 1, 2A, and 2B have been described with reference to FIGS. 4 to 11B. However, those skilled in the art will appreciate that semiconductor devices having various modified and changed structures may be manufactured from the semiconductor devices 100, 100a, and 100b illustrated in FIGS. 1, 2A, and 2B through various modifications and changes within the scope of the inventive concept.

While aspects of example embodiments have been particularly shown and described, it will be understood that various changes in form and details may be made therein without departing from the spirit and scope of the following claims.

What is claimed is:

1. A semiconductor device comprising:
a substrate;
an active region extending in a first direction on the substrate;
a plurality of channel layers stacked on the active region and spaced apart from each other in a vertical direction perpendicular to the first direction;
a gate structure extending on the active region in a second direction perpendicular to the first direction and the vertical direction, and surrounding the plurality of channel layers;
a source/drain region provided on at least one side of the gate structure on the active region and electrically connected to the plurality of channel layers; and
a plurality of anti-diffusion layers stacked and spaced apart from each other in the vertical direction and extending in the second direction,
wherein the plurality of anti-diffusion layers comprise a Si₁₋ₓGeₓ layer (here, x≠0), and the plurality of anti-diffusion layers are located only between the source/drain region and the plurality of channel layers to discontinuously extend in the vertical direction.

2. The semiconductor device of claim 1, wherein a thickness of each of the plurality of anti-diffusion layers in the first direction is about 0.1 nm to about 1 nm.

3. The semiconductor device of claim 1, wherein the plurality of anti-diffusion layers are configured to prevent an N-type dopant diffusing from the source/drain region from reaching the plurality of channel layers.

4. The semiconductor device of claim 1, wherein the source/drain region comprises a first layer, a second layer, and a third layer sequentially stacked from outside the active region,
wherein the first layer, the second layer, and the third layer comprise Si or SiC, and
wherein the second layer is doped with an N-type dopant at a first concentration and the third layer is doped with an N-type dopant at a second concentration different from the first concentration.

5. The semiconductor device of claim 4, wherein the first layer comprises an undoped Si layer.

6. The semiconductor device of claim 4, wherein the N-type dopant doped in the second layer comprises arsenic (As).

7. The semiconductor device of claim 4, wherein the N-type dopant doped in the third layer comprises phosphorus (P), arsenic (As), antimony (Sb), or a mixture thereof.

8. The semiconductor device of claim 1, wherein the gate structure comprises:
a gate electrode extending in the second direction on the active region;
a gate insulating layer surrounding the gate electrode; and
a gate spacer covering a side of the gate insulating layer,
wherein the gate electrode comprises a main gate electrode extending in the second direction on the plurality of channel layers and at least one sub-gate electrode located between each of the plurality of channel layers,
wherein the source/drain region faces the plurality of channel layers with the plurality of anti-diffusion layers therebetween in the first direction, and
wherein the plurality of anti-diffusion layers are offset from regions between the source/drain region and the sub-gate electrode.

9. The semiconductor device of claim 8, further comprising internal spacers located between the sub-gate electrode and the source/drain region on the active region and spaced apart from each other in the vertical direction.

10. The semiconductor device of claim 1, further comprising a source/drain capping layer on an upper surface of the source/drain region in the vertical direction,
wherein the source/drain capping layer comprises an undoped Si layer or a Si layer with an N-type dopant.

11. A semiconductor device comprising:
an active region extending in a first direction on a substrate;
a plurality of source/drain regions provided on the active region;
a plurality of channel layers provided on at least one side of and spaced apart from each of the plurality of source/drain regions in the first direction, electrically connected to the plurality of source/drain regions, and spaced apart from each other in a vertical direction perpendicular to the first direction;
a plurality of anti-diffusion layers located on both sides of each of the plurality of source/drain regions on the active region and spaced apart from each other in the vertical direction;
a gate structure extending in a second direction perpendicular to the first direction and the vertical direction on the active region, and surrounding the plurality of channel layers; and
a source/drain capping layer on an upper surface of the plurality of source/drain regions in the vertical direction,
wherein a source/drain region of the plurality of source/drain regions is bilaterally symmetrical based on a central axis of the source/drain region,
wherein the plurality of anti-diffusion layers comprise a Si₁₋ₓGeₓ layer (here, x≠0),
wherein a thickness of each of the plurality of anti-diffusion layers in the first direction is about 0.1 nm to about 1 nm, and
wherein the plurality of anti-diffusion layers are provided between the source/drain region and the plurality of channel layers, and discontinuously extend in the vertical direction.

12. The semiconductor device of claim 11, wherein, when viewed in the second direction, a portion of one of the plurality of anti-diffusion layers facing the source/drain region has a rectangular shape parallel to a side of a channel layer in the first direction.

13. The semiconductor device of claim 11, wherein, when viewed in the second direction, a portion of one of the plurality of anti-diffusion layers facing the source/drain region has one of a rounded circular arc shape, a shape with a rounded semicircular recess facing a channel layer, and a triangle shape with a peak point.

14. The semiconductor device of claim 11, wherein the source/drain region comprises a first layer, a second layer, and a third layer sequentially stacked from outside the active region,
wherein the first layer, the second layer, and the third layer comprise an Si layer or an SiC layer, and
wherein the second layer is doped with an N-type dopant at a first concentration and the third layer is doped with an N-type dopant at a second concentration different from the first concentration.

15. The semiconductor device of claim 14, wherein the first layer comprises an undoped Si layer,
wherein the N-type dopant doped in the second layer comprises arsenic (As), and
wherein the N-type dopant doped in the third layer comprises phosphorus (P), arsenic (As), antimony (Sb), or a mixture thereof.

16. The semiconductor device of claim 14, wherein thicknesses of the first layer, the second layer, and the third layer are different from each other, and
wherein the thickness of the third layer is greater than the thicknesses of the first layer and the second layer.

17. The semiconductor device of claim 11, wherein the gate structure comprises:
a gate electrode extending in the second direction on the active region;
a gate insulating layer surrounding the gate electrode;
a gate spacer covering a side of the gate insulating layer; and
a gate capping layer on the gate electrode,
wherein the gate electrode comprises a main gate electrode extending in the second direction on the plurality of channel layers and at least one sub-gate electrode located between each of the plurality of channel layers,
wherein a length of the sub-gate electrode in the first direction is less than or equal to a length a channel layer in the first direction,
wherein the source/drain region faces the plurality of channel layers with the plurality of anti-diffusion layers therebetween in the first direction, and
wherein the plurality of anti-diffusion layers are offset from regions between the source/drain region and the sub-gate electrode.

18. The semiconductor device of claim 17, further comprising internal spacers between the sub-gate electrode and the source/drain region on the active region, spaced apart from each other in the vertical direction, and extending in the second direction,
wherein the internal spacers comprise SiN, SiO₂, and a mixture thereof.

19. A semiconductor device comprising:
an active region extending in a first direction on a substrate;
a plurality of channel layers spaced apart from each other in a vertical direction perpendicular to the first direction on the active region and facing an upper surface of the active region;
source/drain regions located on both sides of the plurality of channel layers on the active region and electrically connected to the plurality of channel layers; and
a plurality of anti-diffusion layers spaced apart from each other in the vertical direction on the active region and extending in a second direction perpendicular to the first direction,
wherein the plurality of anti-diffusion layers comprise a Si₁₋ₓGeₓ layer (here, x≠0),
wherein the plurality of anti-diffusion layers are provided between a source/drain region, among the source/drain regions, and the plurality of channel layers and discontinuously extend in the vertical direction,
wherein the plurality of anti-diffusion layers are configured to prevent an N-type dopant diffusing from the source/drain region from reaching the plurality of channel layers,
wherein the source/drain region comprises a first layer, a second layer, and a third layer sequentially stacked from outside the active region,
wherein the first layer, the second layer, and the third layer comprise an Si or SiC layer,
wherein the second layer doped with an N-type dopant at a first concentration and the third layer is doped with an N-type dopant at a second concentration different from the first concentration, and
wherein, when viewed in the second direction, a portion of one of the plurality of anti-diffusion layers facing the source/drain region has one of a rectangular shape parallel to a side of a channel layer in the first direction, a rounded circular arc shape, a shape with a rounded semicircular recess facing the channel layer, and a triangle shape with a peak point.

20. The semiconductor device of claim 19, further comprising:
a main gate electrode extending in the second direction on the plurality of channel layers;
a sub-gate electrode integrally connected to the main gate electrode, and located between the substrate and the plurality of channel layers;
a gate insulating layer surrounding each of the main gate electrode and the sub-gate electrode;
a gate capping layer provided on the main gate electrode; and
internal spacers located between the sub-gate electrode and the source/drain region on the active region, spaced apart from each other in the vertical direction, and extending in the second direction,
wherein the source/drain region faces the plurality of channel layers with the plurality of anti-diffusion layers therebetween in the first direction, and
wherein the plurality of anti-diffusion layers are offset from regions between the source/drain region and the sub-gate electrode.
